(19) United States
(12) Patent Application Publication
(10) Pub. No.: US 2022/0147853 A1
(43) Pub. Date: May 12, 2022

(54) METHOD FOR VALIDATING SIMULATION MODELS

(71) Applicant: Robert Bosch GmbH, Stuttgart (DE)

(72) Inventors: Péter Vass, Budapest (HU); Johannes Von Keler, Tuebingen (DE); Julian Schmidt, Tuebingen (DE)

(21) Appl. No.: 17/453,605

(22) Filed: Nov. 4, 2021

(30) Foreign Application Priority Data
Nov. 10, 2020 (DE) 10 2020 214 098.7

(51) Int. Cl. G06N 7/00; G06F 17/16

(52) U.S. Cl. CPC G06N 7/005; G06F 17/16

(57) ABSTRACT

A computer-implemented method for validating simulation data of a simulation model of a technical system. The method includes: providing simulation data including a number of simulation signals and providing reference data including a number of reference signals, the simulation signals and reference signals being multidimensional signals, at least two-dimensional signals; and determining a score map between a first probability distribution including the simulation data and a second probability distribution including the reference data using the Wasserstein metric, the determination of the score map including: creating a score matrix based on the simulation signals and the reference signals; converting the score matrix into a cost matrix; calculating optimal transport costs for the cost matrix, and converting the optimal transport costs into the score map.

### FIELD

The present invention relates to a computer-implemented method for validating simulation data of a simulation model of a technical system.

Further specific embodiments of the present invention relate to a computer program and/or to a device for carrying out the method.

Further specific embodiments of the present invention relate to the use of the computer-implemented method and/or of the computer program and/or of the device for validating a simulation model of a technical system, in particular, software, hardware or an embedded system, in particular, in the development of the technical system.

### BACKGROUND INFORMATION

Reference data are usually collected for validating a simulation model at particular points in the parameter space of the simulation model—at the so-called validation points. These reference data generally originate from real validation experiments or from simulation runs of a highly accurate reference model. A so-called model error is calculated at the validation points, a real scalar variable, which indicates the deviation between the simulation model and the reference.

So-called score functions may be used for determining the deviation of the simulation data from the reference data or to determine the match between simulation data and reference data.

The score functions provide values at an interval of [u,v]⊂ [symbol] , for example, 0.1. Value u, a lower limiting value, for example 0, stands for a poor match or a high deviation. Value v, an upper limiting value, for example, 1 or 100, stands for a good match, for example, a hundred percent match, or no deviation. The score function in this case is established in such a way that the score of a signal in relation to itself results in the upper limiting value, for example, s(x(t))=v. The values provided by the score function are suitable, in particular, for a qualitative assessment. Score functions are usually used, in particular, in conjunction with time series signals.

The reference signals originate, for example, from real measurements or from a reference model and therefore usually have a natural variability. For example, various parameters may vary during various measurement cycles. Regardless of how well the attempt is made to control all parameters of a measurement, some of them will vary during each measurement cycle. Assuming a deterministic simulation model, the simulation in the case of fixed parameters would always provide the same result. Therefore, the experiment in the simulation is re-modelled by randomly varying some of the parameters and recording the results. If these parameters, which are referred to as aleatoric parameters, are distributed in the correct manner, the respective simulation data set will be very similar to the respective corresponding reference data set if the simulation model correctly reproduces the relevant effects. From a mathematical point of view, the comparison between simulation and reference thus corresponds to the calculation of the distance between probability distributions.

The above-described score function is not suitable for assessing the distance between probability distributions.

To validate scalar signals, a validation framework, for example, is used based on the so-called area validation metric described, for example, in Oberkampf, William L and Christopher J. Roy, “Verification and validation in scientific computing,” Cambridge University Press, 2010. Both the simulation results as well as the reference measurements, which are ideally real experiments, are usually understood as drawings from two different random distributions. This means that an (empirical) distribution function (cumulative distribution function, CDF) is created from the data for both the simulation as well as for the reference. These distribution functions are then compared with one another using a metric, for example, the area validation metric, for distribution functions. In the area validation metric, the area between the two distribution functions is used as a measure for the mismatch between the two distributions. However, the area validation metric is not applicable in the multidimensional case.

An object of the present invention is therefore to provide a method that makes it possible to apply a score function to probability distributions.

### SUMMARY

One specific embodiment of the present invention relates to a computer-implemented method for validating simulation data of a simulation model of a technical system; the method including the following steps:

providing simulation data including a number n of simulation signals and providing reference data including a number m of reference signals, the simulation signals and reference signals being multidimensional signals, at least two-dimensional signals, and determining a score map between a first probability distribution including the simulation data and a second probability distribution including the reference data using the Wasserstein metric, the determination of the score map including:
creating a score matrix based on the simulation signals and the reference signals;
converting the score matrix into a cost matrix;
calculating optimal transport costs for the cost matrix, and converting the optimal transport costs into the score map.

The simulation signals are, for example, output signals of the simulation model. The reference signals are, for example, output signals of a reference model.

The simulation signals of the simulation data and/or the reference signals of the reference data include, for example, scalar signals and/or multidimensional signals, in particular, two-dimensional or multidimensional vectors and/or correlated signals and/or time series signals. Two-dimensional or multidimensional vectors are used, for example, if a spatial orientation is described. Correlated signals are used, for example, in order to combine multiple outputs of a model in order to represent the correlation of the outputs. In time series signals, each point in time at which a signal is recorded is regarded as a separate signal.

The simulation data include a number n of simulation signals where n>1. The reference data include a number m of reference signals where m>1. The number n of simulation signals and/or number m of reference signals may vary in size for various simulation data and/or reference data.

According to an example embodiment of the present invention, therefore, it is provided to initially convert the score matrix including the score values into a cost matrix. Based on the cost matrix, the optimal costs of the cost matrix are calculated using the Wasserstein metric. The optimal costs are then converted back into score values. With the aid of the conversion, it is possible to use the Wasserstein metric in combination with score values.

In principle, the Wasserstein metric may only be applied to functions that are of the cost type. With the aid of the conversion, it is possible using the provided method to use the statistical framework of the Wasserstein distance in combination with score functions.

The use of score functions in turn allows general threshold values for the quality of a simulation model to be defined and is therefore suitable for applications in the assessment of simulation models, in particular, within the scope of vehicle simulation.

According to one specific embodiment of the present invention, it is provided that the creation of the score matrix includes the determination of a score value at an interval of [u,v]⊂ [symbol] of a respective simulation signal to a respective reference signal. The score matrix is an n×m matrix or an m×n matrix. The i−j-th entry of the matrix is the score value of the j-th simulation signal to the i-th reference signal, where 1≤i≤n and 1≤j≤m.

According to one specific embodiment of the present invention, it is provided that the conversion of the score matrix into the cost matrix takes place by applying a linear, in particular, an affine linear transformation function to the score matrix, in particular, by applying the transformation function to each entry of the score matrix.

According to one specific embodiment of the present invention, it is provided that the transformation function is provided by the function ƒ(t):=av−at.

Parameter a may be, in particular, arbitrarily determined. It may prove advantageous, however, if the parameter is a=1/(v−u).

According to one specific embodiment of the present invention, it is provided that the calculation of optimal transport costs for the cost matrix takes place using the Wasserstein distance.

For empirical measurements, i.e., for a finite number of simulation data and reference data, the optimal transport costs correspond to the Wasserstein distance.

According to one specific embodiment of the present invention, it is provided that the conversion of the optimal transport costs into the score map takes place by applying the inverse function of the transformation function to the optimal transport costs.

It may prove advantageous that the score map meets at least one of the following characteristics:
for n=1 and m=1, score map S is reduced to cost matrix s, in particular,

S(x,y)=s(x,y),
for n=1 or m=1, score map S corresponds to the mean value of score matrix s, in particular,

S(x,{yᵢ}_{1≤i≤m})=1/mΣᵢ₌₁^{m}s(x,yᵢ)

or

S({xⱼ}_{1≤j≤n},y)=1/nΣⱼ₌₁ⁿs(xⱼ,y),
score map S itself again results in a score, where S∈I and

S({xⱼ}_{1≤j≤n},{xⱼ}_{1≤j≤n})=v

apply.

Further specific embodiments of the present invention relate to a computer program for validating data of a simulation model, the computer program including computer-readable instructions, upon execution of which by a computer, a computer-implemented method according to the specific embodiments is carried out.

Further specific embodiments of the present invention relate to a device for validating data of a simulation model, the device including a processing unit for carrying out a computer-implemented method according to the specific embodiments.

Further specific embodiments of the present invention relate to the use of a computer-implemented method according to the specific embodiments and/or of a computer program according to the specific embodiments and/or of a device according to the specific embodiments for validating a simulation model of a technical system, in particular, software, hardware or an embedded system, in particular in the development of the technical system. The simulation model is, for example, an HiL, Hardware in the Loop—or an Sil, Software in the Loop,—simulation model. The simulation model is used in this case as a replica of the real surroundings of the technical system. HiL and SiL are methods for testing hardware and embedded systems or software, for example, for support during the development and for early start-up. A simulation-based enablement, for example, may be supported with the use of the method for validating a simulation model of a technical system, in particular, software, hardware or an embedded system, in particular, in the development of the technical system.

The technical system is, for example, software, hardware or an embedded system. The technical system is, in particular, a technical system, for example, a control unit or a software for a control unit, for a motor vehicle, in particular, for an autonomous or semi-autonomous motor vehicle. In the motor vehicle sector, in particular, simulation models frequently include multidimensional signals.

Further features, possible applications and advantages of the present invention result from the following description of exemplary embodiments of the present invention, which are represented in the figures. All features described or represented in this case, alone or in arbitrary combination, form the subject matter of the present invention, regardless of their wording or representation in the description or in the figures.

### BRIEF DESCRIPTION OF THE DRAWINGS

FIG. 1 shows aspects of a computer-implemented method in a schematic representation, in accordance with an example embodiment of the present invention.

FIG. 2 shows aspects of a use of the computer-implemented method from FIG. 1 in a schematic representation, in accordance with an example embodiment of the present invention.

### DETAILED DESCRIPTION OF EXAMPLE EMBODIMENTS

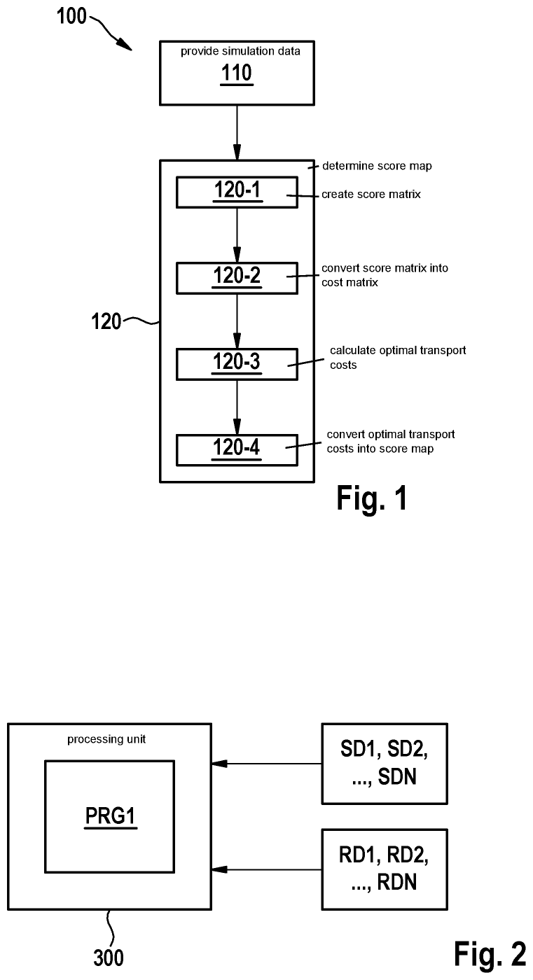

Steps of a computer-implemented method 100 for validating simulation data of a simulation model of a technical system are schematically represented in FIG. 1.

Method 100 includes a step 110 for providing simulation data SD including a number of simulation signals and providing reference data RD including a number of reference signals. The simulation signals and the reference signals are multidimensional, at least two-dimensional, signals.

According to the specific embodiment represented, simulation data SD include a number n of simulation signals where n>1 and reference data RD include a number m of reference signals where m>1.

The multidimensional signals are, for example, two-dimensional or multidimensional vectors and/or correlated signals and/or time series signals. The method is explained below with reference to time series signals, namely simulation signals {xⱼ(t)}_{1≤j≤n} and reference signals {yᵢ(t)}_{1≤i≤m}.

Method 100 further includes a step 120 for determining a score map between a first probability distribution including simulation data SD and a second probability distribution including reference data RD using the Wasserstein metric.

Step 120 for determining the score map according to the specific embodiment represented includes the following steps:

a step 120-1 for creating a score matrix with entries s(xj, yi) based on the simulation signals and the reference signals;
a step 120-2 for converting the score matrix into a cost matrix;
a step 120-3 for calculating optimal transport costs for the cost matrix, and
a step 120-4 for converting the optimal transport costs into the score map.

The creation 120-1 of the score matrix includes determining a score value at an interval of [u,v]⊂ [symbol] for a respective simulation signal to a respective reference signal. The score matrix is an n×m matrix or an m×n matrix. The i−j-th entry of the score matrix is the score value of the j-th simulation signal {xⱼ(t)}_{1≤j≤n} to the i-th reference signal {yᵢ(t)}_{1≤i≤m}. The score value in this case is determined by mapping the score values of N-dimensional signals with the aid of a score function s at an interval I:

s: [symbol] ^{N}× [symbol] ^{N}→I:=[u,v]⊂ [symbol] .

Conversion 120-2 of the score matrix into a cost matrix takes place by applying a linear, in particular, an affine linear transformation function f to the score matrix, in particular, by applying transformation function f to each entry of the score matrix.

Transformation function f according to the specific embodiment represented is

ƒ(t):=av−at.

Transformation function f maps the score matrix according to the specific embodiment represented at interval [0,a(v−u)]:

ƒ(I)=J=[0,a(v−u)].

Step 120-3 for calculating optimal transport costs for the cost matrix takes place using the Wasserstein metric. For empirical measurements, i.e., for a finite number of simulation data and reference data, the optimal transport costs correspond to the Wasserstein distance:

$$\tilde{W} ( {\{ {x}_{j} \}}_{1 \leq j \leq n} , {\{ {y}_{i} \}}_{1 \leq i \leq m} ) := {min}_{M} {\sum }_{i = 1}^{m} {\sum }_{j = 1}^{n} {M}_{i j} ( f ( s ( {x}_{j} , {y}_{i} ) ) \\ where \\ {\sum }_{j = 1}^{n} {M}_{i j} = \frac{1}{m} ∀ i ∈ \{ 1 , … , m \} \\ {\sum }_{i = 1}^{m} {M}_{i j} = \frac{1}{n} ∀ j ∈ \{ 1 , … , n \}$$

Mᵢⱼ being a transport matrix.

Step 120-4 for converting the optimal transport costs into score matrix S takes place according to the specific embodiment represented by applying the inverse function of transformation function ƒ⁻¹ to the optimal transport costs, where:

S({xⱼ}_{1≤j≤n},{yᵢ}_{1≤i≤m}):ƒ⁻¹(\tilde{W}({xⱼ}_{1≤j≤n},{yᵢ}_{1≤i≤m})),

where

$${f}^{- 1} ( t ) := v - \frac{t}{a} .$$

Score map S advantageously meets the following characteristics:

E1 for n=1 and m=1, score map S is reduced to cost matrix s. In this case:

S(x,y)=s(x,y)

applies.
E2 for n=1 or m=1, score map S corresponds to the mean value of score matrix s, for example,

S(x,{yᵢ}_{1≤i≤m})=1/mΣᵢ₌₁^{m}s(x,yᵢ)

or

S({xⱼ}_{1≤j≤n},y)=1/nΣⱼ₌₁ⁿs(xⱼ,y)

E3 The score map itself again results in a score, which means that S∈I and

S({xⱼ}_{1≤j≤n},{xⱼ}_{1≤j≤n})=v

apply.

In the following, it is shown that the score map meets characteristics E1 through E3.

For the case n=m=1, M₁₁=1 applies, and thus also

S(x,Y)=ƒ⁻¹(\tilde{W}(x,y))=ƒ⁻¹(ƒ(s(x,y)))=s(x,y).

For the case n=1 and an arbitrary m≠1, Mᵢ₁=1/m applies and thus

$$\tilde{W} ( x , {\{ {y}_{i} \}}_{1 \leq i \leq m} ) = \frac{1}{m} {\sum }_{i = 1}^{m} f ( s ( x , {y}_{i} ) ) .$$

Because transformation function f is an affine linear function, inverse f⁻¹ is also an affine linear function, where f⁻¹(t)=v−t/a.

The application to \tilde{W} results in this case for score map S in the mean value of score matrix s

$${f}^{- 1} ( \frac{1}{m} {\sum }_{i = 1}^{m} f ( s ( x , {y}_{i} ) ) ) = v - \frac{1}{m a} {\sum }_{i = 1}^{m} f ( s ( x , {y}_{i} ) ) = \frac{1}{m} {\sum }_{i = 1}^{m} ( v - \frac{f ( s ( x , {y}_{i} ) )}{a} = \frac{1}{m} {\sum }_{i = 1}^{m} {f}^{- 1} f ( s ( x , {y}_{i} ) ) = \frac{1}{m} {\sum }_{i = 1}^{m} s ( x , {y}_{i} )$$

From the observation of \tilde{W}({xⱼ}_{1≤j≤n},{yᵢ}_{i≤i≤m}), it may be established that

(ƒ·s)(xⱼ,xⱼ)=ƒ(v)=0.

Thus, the choice of

$$M = \frac{1}{{n}^{2}} Id$$

in the function

$$\tilde{W} ( {\{ {x}_{j} \}}_{1 \leq j \leq n} , {\{ {x}_{j} \}}_{1 \leq j \leq n} ) := {min}_{M} {\sum }_{j = 1}^{n} {\sum }_{j = 1}^{n} {M}_{j j} ( f ( s ( {x}_{j} , {x}_{j} ) )$$

results in zero and following from the application of inverse f⁻¹ of the transformation function is then

S({xⱼ}_{i≤j≤n},{xⱼ}_{1≤j≤n})=v.

Because ƒ·s∈J applies, \tilde{W}∈J and S∈I apply.

FIG. 2 shows a use of method 100 in the validation framework.

Simulation data SD including a number of simulation signals and reference data RD including a number of reference signals are multidimensional signals, in particular, two-dimensional or multidimensional vectors and/or correlated signals and/or time series signals. Two-dimensional or multidimensional vectors are used, for example, if a spatial orientation is described. Correlated signals are used, for example, in order to combine multiple outputs of a model and in order to represent the correlation of the outputs. In time-series signals, each point in time at which a signal is recorded is regarded as a separate signal. A recording of a time series including N points in time is thus represented as an N-dimensional signal.

The simulation model is validated by carrying out method 100, in particular, by executing a computer program PRG1 on a processing unit 300.

Further specific embodiments relate to a use of a computer-implemented method according to the specific embodiments and/or of a computer program according to the specific embodiments for validating a simulation model of a technical system, in particular, software, hardware or an embedded system, in particular, in the development of the technical system.

The simulation model is, for example, an HiL, Hardware in the Loop,—or an SiL, Software in the Loop,—simulation model. The simulation model in this case is used as a replica of the real surroundings of the technical system. HiL and Sil are methods for testing hardware and embedded systems or software, for example for support during the development and for early start-up. A simulation-based enablement, for example, may be supported with the use of the method 100 for validating a simulation model of a technical system, in particular, software, hardware or an embedded system, in particular, in the development of the technical system. An improved simulation model for the development and/or validation of the technical system, and thus advantageously further positive effects, such as enhanced safety, may be provided by the use of method 100.

The technical system is, for example, software, hardware or an embedded system. The technical system is, in particular, a technical system, for example, a control unit or a software for a control unit, for a motor vehicle, in particular, for an autonomous or semi-autonomous motor vehicle. It may, in particular, also be a safety-relevant technical system.

Simulation models frequently include multidimensional signals, in particular, in the motor vehicle sector. Two-dimensional or multidimensional vectors are used, for example, in order to describe the orientation of a motor vehicle. Furthermore, correlated signals are used if the simulation model has multiple outputs such as, for example, temperature, pressure and velocity and these signals are generally not independent of one another. Time series signals may also be used if a temporal component of signals is to be taken into account.

The provided method makes it possible in the validation process of a simulation model to compare multidimensional signals on the basis of an assessment. In validation processes, in particular, in which score functions have already been used to validate a deterministic simulation, the provided method may be used in order to now validate probability distributions. This has the advantage that the interpretation of the result, for example, threshold values for the assessment of the value of the score functions, does not have to be changed.

1-11. (canceled)

12. A computer-implemented method for validating simulation data of a simulation model of a technical system, the method comprising the following steps:
providing simulation data including a number of simulation signals and providing reference data including a number of reference signals, the simulation signals and reference signals being multidimensional signals, the multidimensional signals being at least two-dimensional signals; and
determining a score map between a first probability distribution including the simulation data and a second probability distribution including the reference data, using a Wasserstein metric, the determination of the score map including:
creating a score matrix based on the simulation signals and the reference signals,
converting the score matrix into a cost matrix,
calculating optimal transport costs for the cost matrix, and
converting the optimal transport costs into the score map.

13. The computer-implemented method as recited in claim 12, wherein the creation of the score matrix includes determination of a score value at an interval of [u,v]⊂ [symbol] of a respective simulation signal to a respective reference signal.

14. The computer-implemented method as recited in claim 13, wherein the conversion of the score matrix into the cost matrix takes place by applying an affine linear transformation function to the score matrix by applying the transformation function to each entry of the score matrix.

15. The computer-implemented method as recited in claim 14, wherein the transformation function is provided by ƒ(t):=av−at.

16. The computer-implemented method as recited in claim 15, wherein parameter a is
$$α = \frac{1}{( v - u )} .$$

17. The computer-implemented method as recited in claim 12, wherein the calculation of the optimal transport costs for the cost matrix takes place using a Wasserstein distance.

18. The computer-implemented method as recited in claim 12, wherein the conversion of the optimal transport costs into the score map takes place by applying an inverse function of the transformation function to the optimal transport costs.

19. The computer-implemented method as recited in claim 12, wherein the score map (S) meets at least one of the following characteristics:
for n=1 and m=1, the score map (S) is reduced to the cost matrix (s):,
S(x,y)=s(x,y),
for n=1 or m=1, the score map corresponds to a mean value of the score matrix (s):
S(x,{yᵢ}_{1≤i≤m})=1/mΣᵢ₌₁^{m}s(x,yᵢ)
or
S({xⱼ}_{1≤j≤n},y)=1/nΣⱼ₌₁ⁿs(xⱼ,y),
the score map (S) itself results again in a score,
S∈I and S({xⱼ}_{1≤j≤n},{xⱼ}_{1≤j≤n})=v
being applicable.

20. The computer-implemented method as recited in claim 12, wherein the multidimensional signals include two-dimensional or multidimensional vectors and/or correlated signals and/or time series signals.

21. A non-transitory computer-readable storage medium on which is stored a computer program including computer-readable instructions for validating simulation data of a simulation model of a technical system, the computer program, when executed by a computer, causing the computer to perform the following steps:
providing simulation data including a number of simulation signals and providing reference data including a number of reference signals, the simulation signals and reference signals being multidimensional signals, the multidimensional signals being at least two-dimensional signals; and
determining a score map between a first probability distribution including the simulation data and a second probability distribution including the reference data, using a Wasserstein metric, the determination of the score map including:
creating a score matrix based on the simulation signals and the reference signals,
converting the score matrix into a cost matrix,
calculating optimal transport costs for the cost matrix, and
converting the optimal transport costs into the score map

22. A device for validating data of a simulation model of a technical system, the device configured to:
provide simulation data including a number of simulation signals and providing reference data including a number of reference signals, the simulation signals and reference signals being multidimensional signals, the multidimensional signals being at least two-dimensional signals; and
determine a score map between a first probability distribution including the simulation data and a second probability distribution including the reference data, using a Wasserstein metric, the determination of the score map including:
creation a score matrix based on the simulation signals and the reference signals,
conversion of the score matrix into a cost matrix,
calculation of optimal transport costs for the cost matrix, and
conversion of the optimal transport costs into the score map.
